(19) United States
(12) Patent Application Publication
(10) Pub. No.: US 2019/0162076 A1
(43) Pub. Date: May 30, 2019

(54) MANAGEMENT OF HEAT CONDUCTION USING PHONONIC REGIONS HAVING NON-METALLIC NANOSTRUCTURES

(71) Applicant: SIEMENS AKTIENGESELLSCHAFT, Münche (DE)

(72) Inventor: Joshua S. MCCONKEY, Orlando, FL (US)

(73) Assignee: SIEMENS AKTIENESELLSCHAFT, München (DE)

(21) Appl. No.: 16/091,694

(22) PCT Filed: Apr. 12, 2016
(86) PCT No.: PCT/US2016/027071

§ 371 Date: Oct. 5, 2018

(51) Int. Cl. F01D 25/12; C23C 14/08; C23C 28/00; F01D 5/28; C04B 35/486

(52) U.S. Cl. CPC F01D 25/12; C23C 14/08; C23C 28/321; F01D 5/288; F23M 2900/05004; F05D 2300/611; F05D 2260/204; F05D 2300/5024; C04B 35/486

(57) ABSTRACT

A gas turbine engine component formed of material having phononic regions. The phononic regions are formed of non-metallic nanostructures. The phononic regions modify the behavior of the phonons and control heat conduction.

### BACKGROUND

Disclosed embodiments are primarily related to gas turbine engines and, more particularly to phonon management in gas turbine engines. However, the disclosed embodiments may also be used in other heat impacted devices, structures or environments.

### DESCRIPTION OF THE RELATED ART

Gas turbines engines comprise a casing or cylinder for housing a compressor section, a combustion section, and a turbine section. A supply of air is compressed in the compressor section and directed into the combustion section. The compressed air enters the combustion inlet and is mixed with fuel. The air/fuel mixture is then combusted to produce high temperature and high pressure gas. This working gas then travels past the combustor transition and into the turbine section of the turbine.

Generally, the turbine section comprises rows of vanes which direct the working gas to the airfoil portions of the turbine blades. The working gas travels through the turbine section, causing the turbine blades to rotate, thereby turning a rotor in power generation applications or directing the working gas through a nozzle in propulsion applications. A high efficiency of a combustion turbine is achieved by heating the gas flowing through the combustion section to as high a temperature as is practical. The hot gas, however, may degrade the various metal turbine components, such as the combustor, transition ducts, vanes, ring segments and turbine blades that it passes when flowing through the turbine.

For this reason, strategies have been developed to protect turbine components from extreme temperatures such as the development and selection of high temperature materials adapted to withstand these extreme temperatures and cooling strategies to keep the components adequately cooled during operation.

Some of the components used in the gas turbine engines are metallic and therefore have very high heat conductivity. Insulating materials, such as ceramic may also be used for heat management, but their properties sometimes prevent them from solely being used as components. Therefore, providing heat management to improve the efficiency and life span of components and the gas turbine engines is further needed. Of course, the heat management techniques and inventions described herein are not limited to use in context of gas turbine engines, but are also applicable to other heat impacted devices, structures or environments.

### SUMMARY

Briefly described, aspects of the present disclosure relate to materials and structures for managing heat conduction in components. For example gas turbine engines, kilns, smelting operations and high temperature auxiliary equipment.

An aspect of the disclosure may be a gas turbine engine having a gas turbine engine component with a first material, wherein phononic transmittal through the first material forms a first phononic wave; and a phononic region located within the gas turbine engine component made of non-metallic nanostructures, wherein phononic transmittal to the phononic region modifies behavior of the phonons of the first phononic wave thereby managing heat conduction.

Another aspect of the present disclosure may be a method for controlling heat conduction in a gas turbine engine. The method comprises forming a phononic region in a gas turbine engine component, wherein the gas turbine engine component has a first material and the phononic region is made of non-metallic nanostructures; and modifying behavior of phonons transmitted through the first material when the phonons are transmitted to the phononic region thereby managing heat conduction.

Still another aspect of the present disclosure may be a gas turbine engine having a gas turbine engine component having a first material, wherein phononic transmittal through the first material forms a first phononic wave; and a nanogrid formed of phononic regions located within the gas turbine engine component, wherein the phononic regions are made of non-metallic nanostructures, wherein phononic transmittal to the phononic region modifies behavior of the phonons of the first phononic wave thereby managing heat conduction.

### BRIEF DESCRIPTION OF THE DRAWINGS

FIG. 1 is a diagram of phonons interacting with a phononic region where a wave property is modified.

FIG. 2 is a diagram of phonons interacting with a phononic region where the mode of propagation is altered.

FIG. 3 is a diagram of phonons interacting with a phononic region where the movement direction of the phonon is changed.

FIG. 4 is a diagram of phonons interacting with a phononic region where the phonons are scattered.

FIG. 5 is diagram of phonons interacting with a phononic region where the phonons are reflected.

FIG. 6 is a diagram of phonons interacting with a phononic region where waves are refracted.

FIG. 7 is a diagram of phonons interacting with a phononic region where the phonons are dissipated.

FIG. 8 is a diagram illustrating boundaries of phononic regions formed of non-metallic nanostructures located in the material of a gas turbine engine component.

FIG. 9 is a diagram illustrating boundaries of phononic regions formed of non-metallic nanostructures located in the material of a gas turbine engine component.

FIG. 10 shows an example of a nanomesh formed on the material of a gas turbine engine component.

FIG. 11 shows an example of an alternative embodiment of layers of non-metallic nanostructures formed on the material of a gas turbine engine component.

FIG. 12 shows an example of non-metallic nanostructures forming nanogrids on the material of a gas turbine engine component.

FIG. 13 shows a diagram of a nanogrid formed on the material of a gas turbine engine component.

### DETAILED DESCRIPTION

To facilitate an understanding of embodiments, principles, and features of the present disclosure, they are explained hereinafter with reference to implementation in illustrative embodiments. Embodiments of the present disclosure, however, are not limited to use in the described systems or methods.

The items described hereinafter as making up the various embodiments are intended to be illustrative and not restrictive. Many suitable items that would perform the same or a similar function as the items described herein are intended to be embraced within the scope of embodiments of the present disclosure.

As disclosed herein, the materials used in the gas turbine engines permit the thermal conductivity of pieces to be modified, such as by being reduced in size, without changing the chemical structure in the majority of the material. Management of heat conduction can be achieved through nanostructure modification to portions of the existing gas turbine engine components. There is no need for a large scale bulk material or chemical changes; however smaller scale modifications consistent with aspects of the instant invention may be made to gas turbine components.

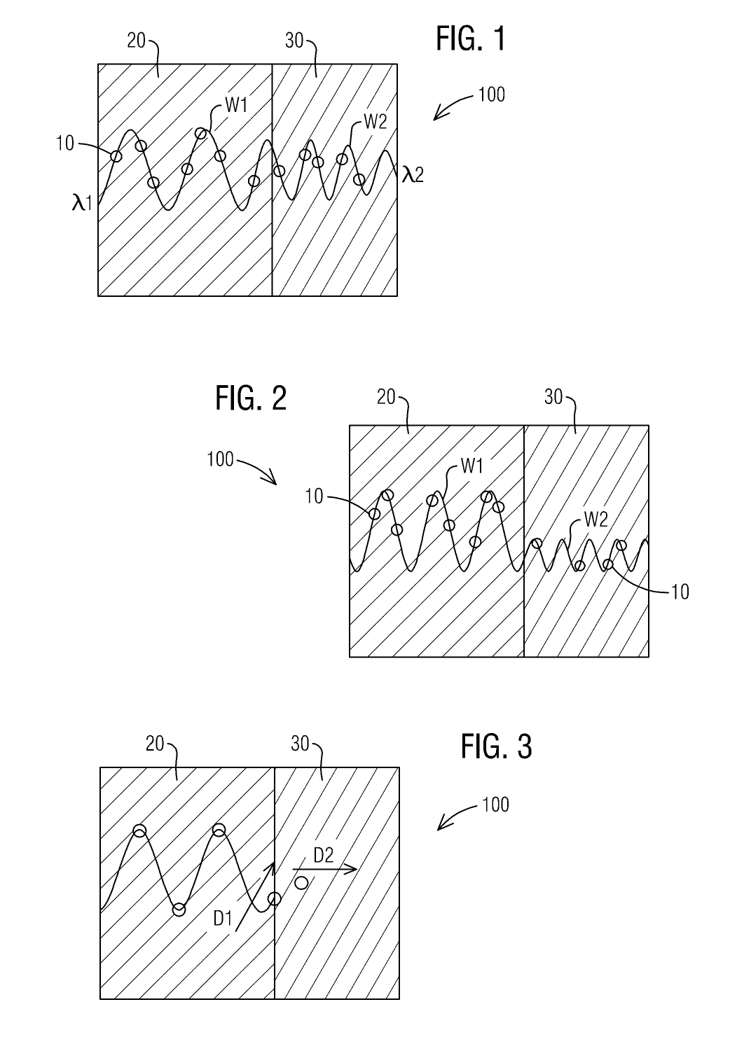

FIG. 1 shows a diagram illustrating the transmission of phonons 10 into a material 20 that is forming part of a gas turbine engine component 100 that can be used in a gas turbine engine. The gas turbine engine component 100 may be a transition duct, liner, part of the combustor, vanes, blades, rings and other gas turbine structures for which heat management would be advantageous. It should also be understood that in addition to gas turbine engine components 100, the management of heat conduction disclosed herein can be applied to other devices for which heat management is important, for example, marine based turbines, aerospace turbines, boilers, engine bells, heat management devices, internal combustion engines, kilns, smelting operations and any other item wherein heat conduction is a design consideration.

The material 20 discussed herein is a metallic material, however it should be understood that other types of materials may be used, such as ceramic and composite materials, when given due consideration for their material properties consistent with aspects of the instant invention. A phonon 10 is generally and herein understood and defined as a quantum of energy associated with a compressional, longitudinal, or other mechanical or electro-mechanical wave such as sound or a vibration of a crystal lattice. Transmissions of phonons 10 collectively transmit heat. The transmissions of phonons 10 form waves in the material 20 as they propagate through the material 20.

In FIG. 1, the phonons 10 are transmitted through the material 20 at a first phononic wave W1. Formed in the material 20 is a phononic region 30. The phononic region 30 is designed to modify the behavior of the phonons 10 as they propagate in the one dimensional (1D), two dimensional (2D) and/or three dimensional (3D) spatial regions in the material 20. The phononic region 30 may modify the behavior of phonons 10 so that they scatter, change direction, change between propagation modes (e.g. change from compression waves to travelling waves), reflect, refract, filter by frequency, and/or dissipate. The modification of the behavior of the phonons 10 controls the heat conduction in the gas turbine engine component 100. The phononic region 30 described herein is formed by non-metallic nanostructures, discussed in detail below, that are formed within the material 20. Non-metallic nanostructures may be formed in the material 20 by introducing a materials, such as cementite or graphene, in the 5-1000 nm range in a particular pattern. Further oxygen could be introduced in order to form ceramics or any other type of non-metallic nanostructure. By “non-metallic” it is meant not having the properties of a metal, for example, not having a crystalline structure that propagates phonons 10 in the same manner as the bulk metallic material 20. For instance, small structures of grapheme are non-metallic, as would be nano-spheres of titania (a ceramic), or powders of carbon or high temperature oxides.

Still referring to FIG. 1, the modification of behavior of the phonons 10 by the phononic region 30 may create a second phononic wave W2. For example, the first phononic wave W1 propagates through the material 20. As the first phononic wave W1 propagates through the material 20 the first phononic wave W1 may have the property of having a first frequency λ₁. When the first phononic wave W1 interacts with the phononic region 30 the behavior of the phonons 10 may form a second phononic wave W2 that has the property of a second frequency λ₂. As the phonons 10 exit from the phononic region 30 and propagate through the material 20 they may continue to propagate at the first frequency λ₁.

The transition from the first frequency λ₁ to the second frequency λ₂ and then back to the first frequency λ₁, helps manage the heat conduction in the material 20. Further, by interspersing the material 20 with a number of phononic regions 30 the fluctuation can disrupt the transmission of phonons 10 so as to manage the propagation of phonons 10 and the heat conduction through the material 20.

FIG. 2 shows a phononic region 30 that modifies the behavior of the first phononic wave W1 to a second phononic wave W2 by changing the property of its mode of propagation. In FIG. 2 the first phononic wave W1 is altered from a travelling wave to the second phononic wave W2 which is a compression wave. However it should be understood that it is contemplated that compression waves could be modified to become travelling waves. By modifying the mode of propagation of the waves the heat conduction through the material 20 may be managed.

FIG. 3 shows a phononic region 30 that modifies the behavior of the phonons 10 by altering the direction of propagation. Phonons 10 may be moving in one direction D1 through material 20 and then change direction to direction D2 as they enter into phononic region 30. By modifying the direction of the phonons 10 the heat conduction through the material 20 may be managed.

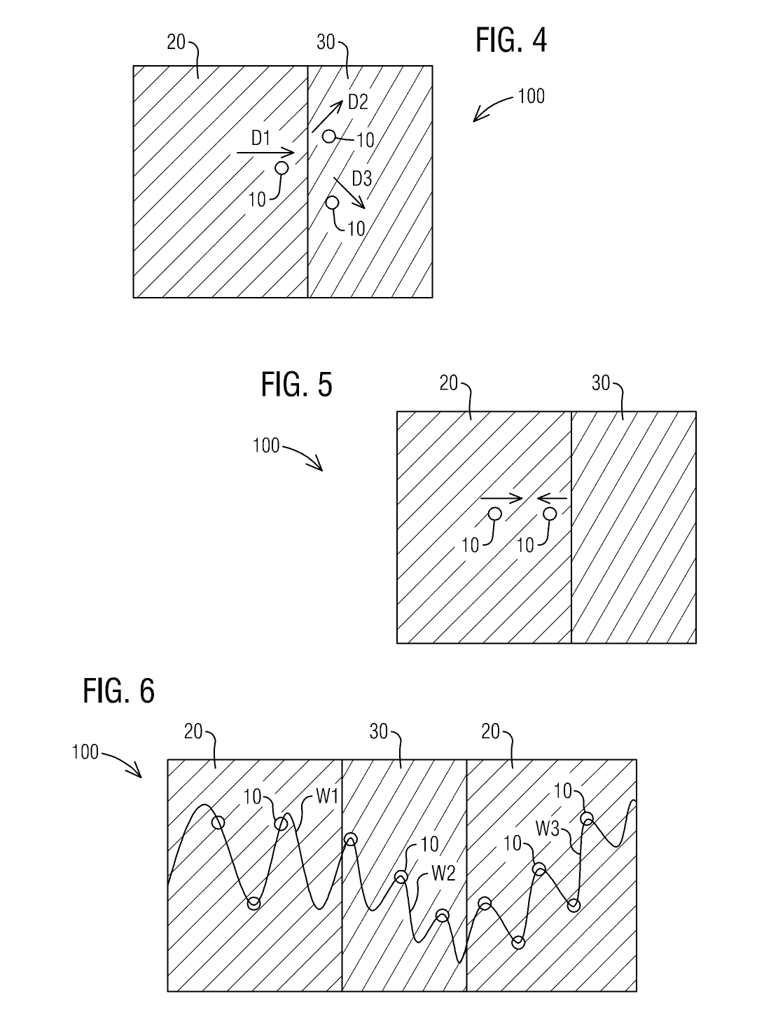

FIG. 4 shows a phononic region 30 that modifies the behavior of the phonons 10 so that the phonons 10 are scattered when they enter the phononic region 30 from the material 20. By scattering it is meant that each phonon 10 that enters the phononic region 30 in direction D1 may propagate in a random different direction D2, D3, etc. By modifying the scattering of the phonons 10 the heat conduction through the material 20 may be managed.

FIG. 5 shows a phononic region 30 that modifies the behavior of the phonons 10 by reflecting the phonons 10 back into the material 20. By modifying the behavior of the phonons 10 so that the phonons 10 are reflected by the phononic region 30 the heat conduction through the material 20 may be managed.

FIG. 6 shows a first phononic wave W1 moving through material 20. When the first phononic wave W1 reaches the phononic region 30 the first phononic wave W1 is modified so that it is refracted and becomes second phononic wave W2 as it passes through the phononic region 30. As the second phononic wave W2 exits the phononic region 30 the phononic wave W2 may be refracted and become a third phononic wave W3. By having the phononic region 30 refract the first phononic wave W1 the heat conduction through the material 20 may be managed.

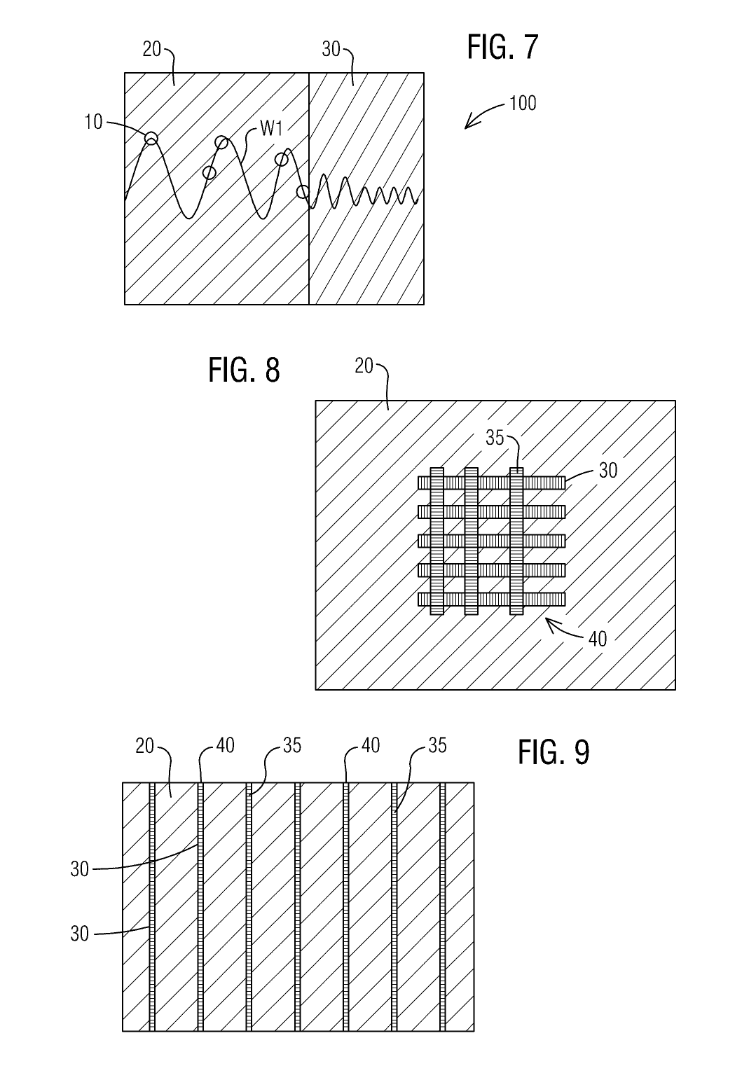

FIG. 7 shows the phononic region 30 located within the material 20 causing phonons 10 from the first phononic wave W1 to dissipate as it exits the material 20. By “dissipate” it is meant that at least some of the phonons 10 cease to travel through the phononic region 30 or cease to exist. By having the phononic region 30 dissipate the phonons 10 the heat conduction through the material 20 may be managed.

FIG. 8 shows an example of the phononic region 30 formed by non-metallic nanostructures 35 within the material 20. The non-metallic nanostructures 35 may form the entirety of the phononic region 30. In the embodiment shown in FIG. 8 the phononic regions are used to form boundaries 40. The material 20 may be metallic in that crystalline structures are formed within the material 20. The non-metallic nanostructures 35 that form the phononic region 30 can be created by introducing various elements during manufacturing of the gas turbine engine component 100. For example carbon can be introduced during the manufacturing process in order to form cementite in a specific pattern. Other methods for forming the non-metallic nanostructures 35 may be the introduction of ceramic nanospheres in 2D layers within the metallic bulk of a component, or scattered throughout a small 3D region of that bulk. Oxides can be grown by heat treatment in an oxidising environment using lasers. Thin films of organics or other carbon-bearing molecules can be applied during intermediate cool manufacturing phases. Pits in the bulk material could be made, and a fine oxide powder could be introduced and sintered into the material.

The acoustic impedance of the non-metallic nanostructures 35 can be significantly different from material 20 that is crystalline metallic material. The phononic regions 30 of non-metallic nanostructures 35 can be formed in a pattern, such that the phononic regions 30 may form boundaries 40 that are used to form grids, stripes, columns, rows and other patterns. The width of the boundaries 40 may be on the scale of 5-1000 nm. The phononic regions 30 formed of non-metallic nanostructures 35 have different acoustic impedances than that of material 20. Further, by introducing uniformity of direction in the material 20, and then using non-metallic nanostructures 35 to form phononic regions 30, sharp changes in the acoustic impedance seen by phonons 10 propagating through the phononic regions 30 can be instantiated. These localized acoustic impedance changes will cause the phonons 10 to behave in the manner discussed above with respect to FIGS. 1-7. Layers of phononic regions 30 can be used to affect heat conduction in the material 20.

FIG. 9 shows a plurality of boundaries 40 formed by the phononic regions 30 in the material 20. The boundaries 40 may be formed by layers or wires formed by phononic regions 30 made of non-metallic nanostructures 35. By introducing a plurality of phononic regions 30 to form thin or thick boundaries 40 of the phononic regions 30 the wave mechanics of phonons 10 can be altered so as to manage heat conduction in the gas turbine engine component 100. The boundaries 40 may be from 5 nm to 1000 nm in width. These sizes correlate with the phononic vibration frequencies of approximately 500 GHz to 100 THZ. Because these phononic regions 30 will have differing phononic impedances, they will modify behavior of the propagating phonons 10 in the material 20, thereby disrupting and reducing heat conduction. These techniques can also be used to direct heat conduction in desired directions, by creating channels of optimal propagation for heat-inducing phonons 10 surrounded by phononic regions 30 modifying behavior of phonons 10.

In each of the above possible ways of managing the heat conduction shown in FIGS. 1-7, phonons 10 interacting with phononic regions 30 on the same scale as their wavelength can modify behavior of phonons 10 to impede propagation of phonons 10 and thus manage heat conduction. The patterns formed by the phononic regions 30 can be used to obtain the modified behavior of the phonons 10 that is desired. For example, patterns of phononic regions 30 parallel to the propagation direction can channel the phonons 10. Patterns of phononic regions 30 normal to the phonons 10 can reflect them. Patterns of phononic regions 30 at an angle with respect to the propagation direction can scatter or reflect phonons 10 at an angle, spots of acoustic impedance change can cause scattering.

The phononic regions 30 may be used in metals and other crystalline material, as well as ceramics. The technique for modifying behavior of the phonons 10 is likely to manage phonons 10 directly more so than thermal free electrons in metals. However, electron propagation may also be affected by the phononic regions 30, in two possible ways. One, electrons in metals are constantly exchanging their energies with phonons 10, so management of the phonons 10 has an effect on electrical propagation. Two, if the electron propagation has any frequency component, it would likely be of similar frequencies as the phonon 10, due to similar interactions that the electrons will have with crystalline structures. In metals control of phonons 10 may have significant impacts on heat conduction that is mediated by thermal free electrons.

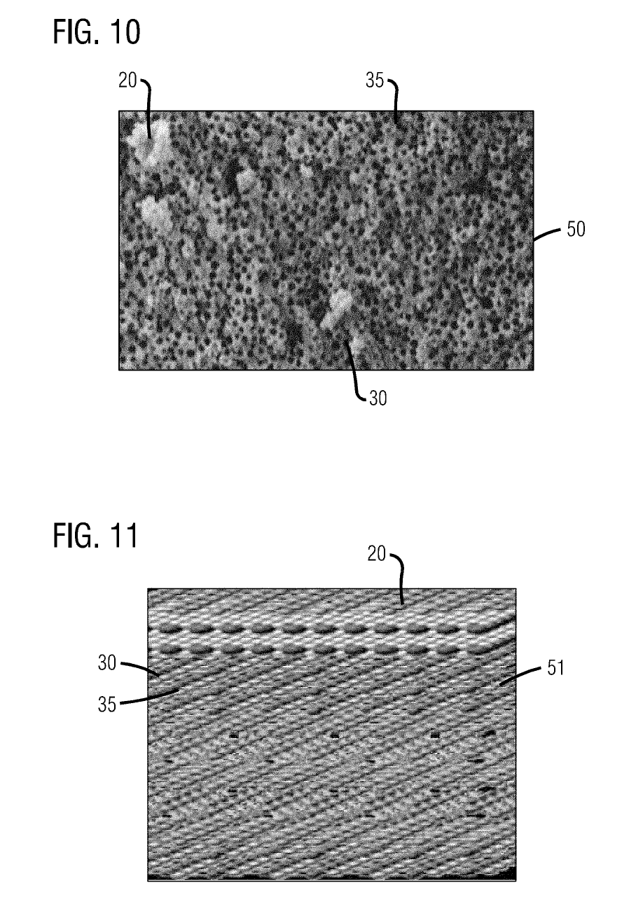

FIG. 10 shows an example of a nanomesh 50 formed on material 20 of the gas turbine engine component 100. In particular, for example, this nanonmesh 50 may be formed on the surface of a vane. The vane may be a modified vane from an existing gas turbine engine component 100, or alternatively the vane may have been formed with the nanomesh 50. Additionally the design of the vane may be modified from an existing vane design or alternatively designed in such a fashion so as to take advantage of the use of the nanomesh 50. The dark spheres are phononic regions 30 made of non-metallic nanostructures 35 which has a different effect on the impedance of phonons 10 than the material 20 formed on the gas turbine engine components 100.

In the embodiment shown, the non-metallic nanostructures 35 may be alumina nanospheres. “Alumina” is a aluminium oxide. The phononic regions 30 forming the nanospheres may have diameters that fall within the range of 5-1000 nm. In the example shown the diameters may be in the range 250 nm-400 nm. By having the phononic regions 30 forming nanospheres, phonons 10 propagating through the material 20 impacting the nanomesh 50 can be managed. The nanomesh 50 can modify the behavior of the phonons 10 by disrupting the propagation and cause the phonons 10 to behave in the manner shown in FIGS. 1-7. The desired behavior can be caused by arranging the nanonmesh 50 to form patterns in the material 20 so that they can be used to manage heat conduction.

FIG. 11 shows an alternative embodiment wherein nanolayers 51 are used in the formation of phononic regions 30. In this embodiment, the nanolayers 51 are formed so that the non-metallic nanostructures 35 are used to form multiple layers within the material 20 of a gas turbine engine component 100. For example, the nanolayers 51 may be formed on the interior surface of a combustor. The combustor may be a modified component from an existing gas turbine engine component 100, or alternatively the combustor may have been formed with the nanolayers 51. Additionally the design of the combustor may be modified from an existing combustor design or alternatively designed in such a fashion so as to take advantage of the use of the nanolayers 51. In this embodiment the nanolayers 51 may have widths of 5-1000 nm and form a plurality of layers between 1-5 mm thick.

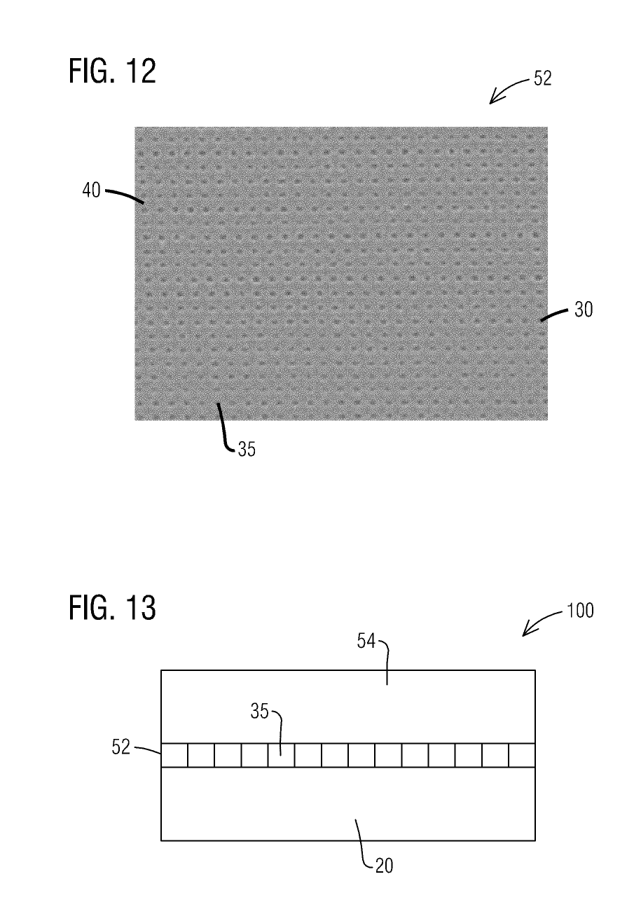

FIG. 12 shows the formation of boundaries 40 made of the non-metallic nanostructures 35 forming the phononic regions 30. In particular, for example, these boundaries 40 may be formed on the surface of a transition duct. The transition duct may be a modified transition duct from an existing gas turbine engine component 100, or alternatively the transition duct may have been formed with the boundaries 40. Additionally the design of the transition duct may be modified from an existing transition duct design or alternatively designed in such a fashion so as to take advantage of the use of the boundaries 40. In this embodiment, the boundaries 40 are formed so as to create a nanogrid 52. The nanogrid 52 is formed from boron nanotubes or carbon nanotubes. The non-metallic nanostructures 35 forming the boundaries 40 may have widths of 5-1000 nm, and may preferably be within the range of 10-30 nm. The boundaries 40 of non-metallic nanostructures 35 forming the nanogrid 52 can modify the behavior of the phonons 10 by disrupting the propagation and cause the phonons 10 to behave in the manner shown in FIGS. 1-7. The desired behavior can be cause by arranging the nanogrid 52 to form patterns of phononic regions 30 in the material 20 so that they can be used to manage heat conduction.

FIG. 13 is diagram illustrating the layered placement of a nanogrid 52 on the material 20 that forms gas turbine engine component 100. For example, the gas turbine engine component 100 may be a combustor. The nanogrid 52 is made of non-metallic nanostructures 35 forming a phononic region 30. The phonoic regions 30 also form the boundaries 40 shown in FIG. 12. The material 20 of the combustor is a metal. The thickness of the material 20 may be between 1 cm to 10 cm. On the surface of the material 20 the nanogrid 52 is formed. The thickness of the nanogrid 52 may be between 5-1000 nm. The nanogrid 52 may be formed in one of the manners discussed above, for example the nanogrid 52 may be formed by depositing carbon nanotubes on the material 20 during the manufacturing of the gas turbine engine component 100. On the surface of the nanogrid 52 a thermal barrier 54 may be placed. The thermal barrier 54 may be made of a heat resistant material, such as ceramic. The thickness of the thermal barrier 54 may be between 1 mm to 5 cm. Once formed the layered structure can be used to manage the propagation of the heat from the interior of the combustor. This can help reduce the stresses that heat may generate in the material 20. This can extend the life span of gas turbine engine components 100.

While embodiments of the present disclosure have been disclosed in exemplary forms, it will be apparent to those skilled in the art that many modifications, additions, and deletions can be made therein without departing from the spirit and scope of the invention and its equivalents, as set forth in the following claims.

1-20. (canceled)

21. A gas turbine engine component comprising:
a first region of a first material and a phononic region, wherein the phononic region comprises non-metallic nanostructures;
wherein phononic transmittal of phonons through the first material forms a first phononic wave; and
wherein, upon transmittal of the first phononic wave to the phononic region, the phononic region is configured to modify a behavior of the phonons of the first phononic wave.

22. The gas turbine engine component of claim 21, wherein the first phononic wave has a first property, wherein the phononic region modifies the behavior of the phonons of the first phononic wave to form a second phononic wave having a second property different than the first property of the first phononic wave.

23. The gas turbine engine component of claim 22, wherein the first property and the second property are frequency.

24. The gas turbine engine component of claim 22, wherein the first property and the second property are modes of propagation.

25. The gas turbine engine component of claim 21, wherein the phononic region modifies the behavior of the phonons of the first phononic wave so that the phonons of the first phononic wave change direction of propagation.

26. The gas turbine engine component of claim 21, wherein the phononic region modifies the behavior of the phonons of the first phononic wave so that the phonons of the first phononic wave scatter.

27. The gas turbine engine component of claim 21, wherein the phononic region modifies the behavior of the phonons of the first phononic wave so that the phonons of the first phononic wave are reflected.

28. The gas turbine engine component of claim 21, the phononic region modifies the behavior of the phonons of the first phononic wave so that the phonons of the first phononic wave are refracted.

29. The gas turbine engine component of claim 21, wherein the phononic region modifies the behavior of the phonons of the first phononic wave so that the phonons of the first phononic wave are dissipated.

30. The gas turbine engine component of claim 21, wherein the phononic region comprises a nanomesh of the non-metallic nanostructures.

31. The gas turbine engine component of claim 21, wherein the non-metallic nanostructures comprise a member from the group consisting of cementite, graphene, and an oxide.

32. A method for controlling heat conduction in a gas turbine engine comprising:
forming a phononic region in a gas turbine engine component, the gas turbine engine component comprising a first region of a first material, wherein the phononic region comprises non-metallic nanostructures;
transmitting phonons through the first material to form a first phononic wave;
transmitting the first phononic wave to the phononic region, and
modifying a behavior of the phonons of the first phononic wave in the phononic region to manage heat conduction.

33. The method of claim 32, wherein the first phononic wave has a first property, wherein the phononic region modifies the behavior of the phonons of the first phononic wave to form a second phononic wave having a second property different than the first property of the first phononic wave.

34. The method of claim 33, wherein the first property and the second property are frequency or modes of propagation.

35. The method of claim 32, wherein the modified behavior of the phonons of the first phononic wave is a changed direction of propagation of the phonons of the first phononic wave.

36. The method of claim 32, wherein the modified behavior of the phonons of the first phononic wave is at least one of scattering, reflection, refraction, or dissipation of the phonons of the first phononic wave.

37. The method of claim 32, wherein the non-metallic nanostructures comprise a member from the group consisting of cementite, graphene, and an oxide.
